(19) United States
(12) Patent Application Publication
(10) Pub. No.: US 2007/0243649 A1
(43) Pub. Date: Oct. 18, 2007

(54) Centrifugally Cast Electrochemical Cell Components

(76) Inventor: Kirby W. Beard, Norristown, PA (US)

Correspondence Address: KRAJEC PATENT OFFICES, LLC, 820 WELCH AVENUE, BERTHOUD, CO, 80513, US

(21) Appl. No.: 11/734,871

(22) Filed: Apr. 13, 2007

Related U.S. Application Data
(60) Provisional application No. 60/791,957, filed on Apr. 14, 2006.

(51) Int. Cl. H01L 21/00

(52) U.S. Cl. 438/30

(57) ABSTRACT

A component for an electrochemical cell is formed using centrifugal forces to densify an electrode or electrode material. In some embodiments, a binding agent may be used to mechanically bind active material for processing and normal operation. The binding agent may be a dispersed solid material as well as a pore forming material. Centrifugal casting may be used to densify electrode films for lithium ion batteries, as well as densification of other materials in various forms used in batteries, capacitors, fuel cells, sensors, and other electrochemical devices. In some embodiments, multiple layers of a device may be constructed using single or plural centrifugal processing steps.

### CROSS REFERENCE TO RELATED APPLICATIONS

This application claims the benefit of and priority to U.S. Provisional Patent Application Ser. No. 60/791,957, filed Apr. 14, 2006 entitled “Centrifugally Cast Electrochemical Cell Components” by Kirby W. Beard, the entire contents of which are hereby expressly incorporated by reference.

### BACKGROUND

Electrochemical cells, such as batteries, capacitors, fuel cells, sensors, and other devices are generally made up of active material that generates or responds to electrical energy. In many such cells, the electrical energy may be generated by oxidation and reduction reactions at two coupled electrodes in the device.

In a typical cell, an electrode may contain active material that reacts or interacts with an electrolyte that conducts ions to a second electrode with different active material. An electrical potential may be created across the electrodes by the electrochemical interaction between the active materials of two electrodes and electrolyte. Many different compositions of active material and electrolytes are used for different types of electrochemical cells. A typical electrochemical cell may be a lithium-ion battery commonly used in today's electronic devices.

The efficiency and power capability of an electrode may be dependent on how much active material is available but with a sufficient amount of porosity so that electrolyte may contact and react with the active material. In many cases, a binder may be used to hold the active material in an electrode, which detracts from the porosity, sometimes significantly.

### SUMMARY

A component for an electrochemical cell is formed using centrifugal forces to densify an electrode or electrode material. In some embodiments, a binding agent may be used to mechanically bind active material for processing and normal operation. The binding agent may be a dispersed solid material as well as a pore forming material. Centrifugal casting may be used to densify electrode films for lithium ion batteries, as well as densification of other materials in various forms used in batteries, capacitors, fuel cells, sensors, and other electrochemical devices. In some embodiments, multiple layers of a device may be constructed using single or plural centrifugal processing steps.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

In the drawings,

FIG. 1 is a diagram illustration of an embodiment showing a schematic cross-section of an electrochemical device.

FIG. 2 is a flowchart illustration of an embodiment showing a method for fabricating an electrochemical device.

FIG. 3 is a diagram illustration of an embodiment showing a schematic cross-section of an electrode with porous or conductive binder.

FIG. 4 is a diagram illustration of an embodiment showing a schematic cross-section of an electrode with an integral separator.

FIG. 5 is a diagram illustration of an embodiment showing a schematic cross-section of an electrode with a solid binder.

### DETAILED DESCRIPTION

A centrifuge may be used in the manufacturing process for an electrochemical device to compact or densify active material used as an electrode for devices such as batteries, capacitors, sensors, fuel cells, and other devices. The centrifugal processing may enable a dense packing of the active material but still allow electrolyte or other conductive material to contact the active material and thus enable the device to perform. The electrolyte may contact the active material through residual porosity, liquid permeability, or ion conductivity through the electrode.

A binder may be used to hold the active material in place for processing and durability. The binder may be any type of suitable solid or porous material, such as a polymer binder that may be added using various formulations and techniques for creating porosity in the centrifugally processed material.

Specific embodiments of the subject matter are used to illustrate specific inventive aspects. The embodiments are by way of example only, and are susceptible to various modifications and alternative forms. The appended claims are intended to cover all modifications, equivalents, and alternatives falling within the spirit and scope of the invention as defined by the claims.

Throughout this specification, like reference numbers signify the same elements throughout the description of the figures.

When elements are referred to as being “connected” or “coupled,” the elements can be directly connected or coupled together or one or more intervening elements may also be present. In contrast, when elements are referred to as being “directly connected” or “directly coupled,” there are no intervening elements present.

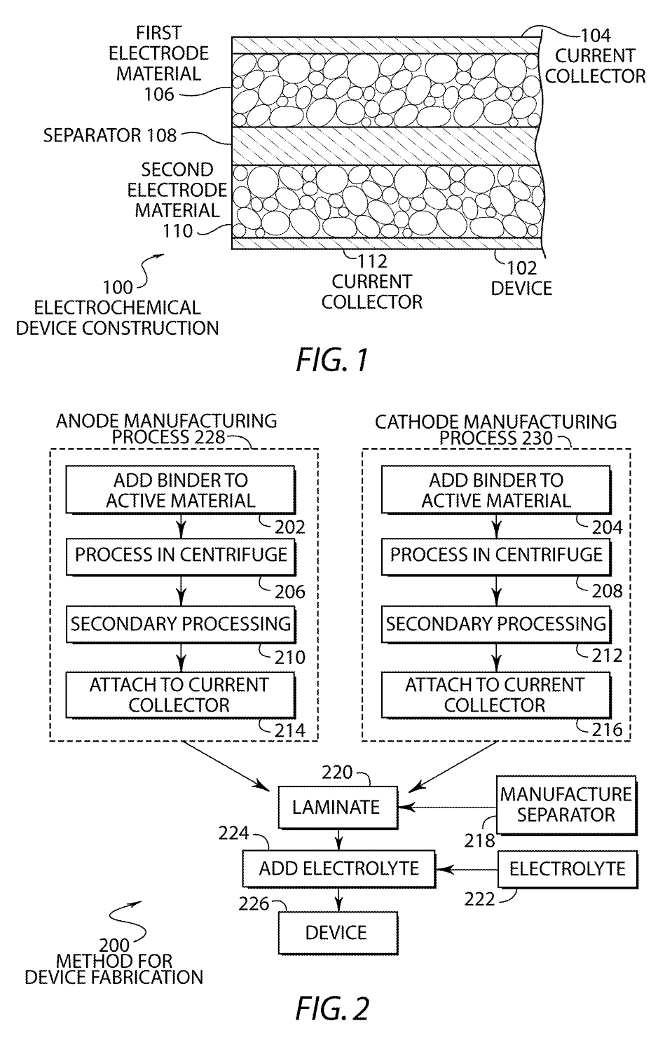

FIG. 1 is a schematic diagram of an embodiment 100 showing a cross section of an electrochemical device such as a battery or capacitor. Embodiment 100 may be manufactured using a centrifugal processing step for densification of the various active material that make up the electrochemical device. Binders may be used during the centrifugal processing step to bind the active materials. In some embodiments, the centrifugal processing step may include attaching active materials to a current collector, adding a separator and second electrode, forming an integral separator in a single processing step, and other variations. In other embodiments, centrifugal processing may be used to densify active material prior to secondary processing to form the actual electrode.

The centrifugal processing step applies a large amount of force on the materials being processed, in some cases several thousand times the force of gravity. The large forces may cause tight packing of the active material, giving the resultant device a high power per unit volume to non-centrifuge processed devices.

Centrifugal processing may be applied to any type of battery and material formulation. Because of the higher density of active material in an electrode with centrifugal processing, porous binders or reduced quantities of solid binders may be used. Throughout this specification, a solid binder may refer to a binder material that is generally solid throughout its bulk where the solid binder is present. This is in contrast to a porous binder that may be formed with pores throughout the volume in which the binder resides. In some embodiments, binders, both solid and porous, may be dispersed through active material without being continuous. In many cases, a porous binder may be formed with additional materials and processing steps than a solid binder.

The device 102 has a first current collector 104 which is in contact with a first electrode material 106. A separator 108 is separates the first electrode material 106 from the second electrode material 110, which is attached to a second current collector. Not shown is an electrolyte that may conduct ions between the first electrode material 106 and second electrode material 110.

Embodiment 100 is a typical construction for many types of batteries, capacitors, fuel cells, or other electrochemical devices. In general, the devices may operate by storing or producing electrical current through various reactions between or among the two electrodes and/or the electrolyte.

The electrolyte may be any suitable material. In some cases, such as lead acid batteries and lithium ion batteries, the electrolyte may be a liquid. Dry cell batteries may use an electrolyte that is a paste or gel material. Other batteries may use a solid electrolyte, such as solid state lithium batteries using ion conductive glass or solid polymer.

Each electrode may have different materials to form an anode and cathode for the device. The efficiency and storage capacity of a device may be dependent on the amount of active material within the electrode and the surface area of the active material available for electrolyte contact. As the density of an electrode increases, the porosity may decrease.

The active material in a particular type of battery or other device may be specific for the type of battery. For a typical lithium ion battery construction, the active material in an electrode may be LiCoO2, MCMB carbon, and graphite. Other battery or capacitor devices may use different active materials.

In many electrode constructions, a binder may be used to bind the electrode together for handling, processing, and durability. The binder may be conductive in some designs, however, many binders are nonconductive. Nonconductive binders may contribute to the mechanical properties of the electrode but may interfere or detract from the ionic conduction between electrolyte and active material. In lithium ion battery technology, common materials used in binders may include various polymers including polyvinylidene difluoride (PVDF), polytetrafluoroethylene (PTFE), and others. In some embodiments, graphite powder may be used to engage or otherwise mechanically bind active material together.

An example of a conductive binder may be a conductive glass or other conductive solid that may conduct ions to the active material without a separate electrolyte solution permeating the active material. Other conductive binders may include gels or thick pastes. Some polymers, such as PVDF, PEO, PVDF-HFP, PMMA, and others may be made conductive for some battery applications. Solid polymer electrolytes or binders may have conductances orders of magnitudes lower than their liquid electrolyte counterparts. In general, solid electrolytes perform better when the thickness of the electrolyte is thin as possible, thus the higher compaction gained with a centrifugal processing step may improve the performance of devices using such solid electrolytes.

A binder may be mixed with active material into a liquid, slurry, suspension, gel, solution, paste, or other transport mechanism and processed in a centrifuge. In some embodiments, the centrifugal processing may remove excess solvents or other transport media to form a consolidated paste or solid electrode. In order to form a solid electrode, liquid transport media may be evaporated away, drawn off, or otherwise removed during the centrifugal processing.

In one method, a slurry or suspension of binder and active material may be introduced in a spinning centrifuge and sprayed or otherwise deposited onto the rotating cylindrical surface of the centrifuge. The denser particles of active material and binder may consolidate against the inner surface of the rotating cylinder, pushing the liquid transport media to the inside. The liquid transport media may be drawn off. In some instances, the centrifugal processing may be performed under vacuum to evaporate off the transport media or produce other effects, such as creating pores within the bulk of the binder material.

In general, centrifugal processing may be used when the specific gravity of the active material is within 20 percent of the specific gravity of the binder material. When large differences between the binder and active material exist, higher centrifugal forces or longer processing time may cause the heavier material to separate from the lighter material. In some embodiments, such separation may be desired to achieve different effects, such as creating an integral separator layer.

Centrifugal processing may also be used when a transport medium, such as a liquid or gas, is used to transport and introduce the active material and binder to the centrifugal process. The transport medium may be extracted during centrifuging or a subsequent process. A typical transport medium may be a liquid in which particulate active material and particulate binder is suspended. Other transport media may include a solvent in which some or both of the active material and/or binder is dissolved. In some embodiments, air, an inert gas, or other gas may be used as a transport medium.

In some embodiments, a transport medium may include two or more components. For example, one component may be a solvent in which a binder is dissolved and a second component may be a pore forming agent that is extracted in a secondary process after a centrifugal process step.

In many embodiments with a transport medium, the specific gravity of the transport medium may be 10 or 20 percent different than that of the active material and binder. In general, the transport medium may be drawn off when the specific gravity of the active material is 10 percent greater than the specific gravity of the transport medium.

Binding active materials with a binder may be performed in many different ways. In an example, a PTFE binder may be manufactured using an aqueous PTFE dispersion that may be processed with active material to form an electrode. As the aqueous transport material is removed by centrifugal processing and any subsequent post processing, PTFE may be dispersed through the active material, forming active material bound with PTFE. In some cases, additional processing, such as pressing, calendaring, or filtering may be used to complete the water removal after centrifugal processing. By controlling the amount of PTFE or other binder, a solid binder may form that leaves sufficient porosity for electrolyte conductance.

Other binder materials may include polymer latex solutions, including acrylics, PVDF, PVC, epoxies, urethanes, and other materials.

Some binders may be processed with various mechanisms for creating porosity within the bulk of the binder. Porosity may enable enhanced electrolyte conduction in the electrode. Any pore forming mechanism may be used to create pores in a binder. For example, a combination of solvent and non-solvent may be used to dissolve a binder, transport the binder material, precipitate the binder with the non-solvent present, and then subsequently remove the non-solvent to form pores. The non-solvent may be removed by various techniques such as extraction, leaching, evaporation, or other processes.

Other mechanisms or techniques may be used to create porosity in a binder, including forming gases or liquids due to reactions taking place during the manufacturing process. In another example, a binder may be processed with a solid, liquid, or gas pore forming material that is subsequently removed by evaporation, mechanical working, leaching, or other type of extraction process. Still other mechanisms may include formulations where a binder swells during processing to become permeable or to form pores in a later process step.

Centrifugal processing may be performed in multiple steps to compact and bind active material. For example, a first step may include introducing a binder and active material in a transport media. The transport media may be a liquid, for example. The initial centrifugal processing may perform consolidation of the active material and binder at a first rotational speed. A second processing step may include applying vacuum to the centrifuge and increasing or decreasing the rotational speed.

In forming an electrode, centrifugal processing may be used to densify active material with or without a binder during processing. The centrifugal processing may consolidate and pack the active material to greatly improve density of the active material. Higher density electrodes may be used for smaller devices or devices with additional capacity and a similar size to electrodes that are processed without centrifugal packing.

When forming an electrode, the active material may be centrifugally processed on top of a current collector. The current collector may be a film, sheet, grid, mesh, or other form of a planar electrically conductive material; or fibers, wires, powders or other dispersed network of electrically conductive and interconnected materials. When consolidated using the centrifugal process, the current collector may add some structural integrity to the active material and a binder may or may not be used. In some instances, a binder may be applied after centrifugal processing by coating a surface or infusing the consolidated active material with a binder.

In many cases, increased compaction may be realized with spherical, oblong, or other similar shapes. Mixes of different sizes of material particles, such as particle sizes that range between 10 or 100 times the smallest particle size, may also increase compaction density with a centrifugal processing step. Materials with odd or complex shapes may not compact as readily, however some improvement may be achieved with centrifugal processing.

In some embodiments, multiple layers may be created by a sequence of adding materials to a rotating centrifuge. A first layer of active material and binder may be added to a centrifuge and consolidated into a first layer. A second layer acting as a separator may then be formed by adding additional porous binder material or a separator material. A third layer comprising active material and binder may be then added to form three layers in a single centrifugal process. In some embodiments, a highly electrically conductive material may be used to form current conductor layers as well. Additional layers may also include shutdown layers designed to halt battery operation during an over temperature incident.

An integral separator layer may be formed in a single centrifugal process by using a relatively high ratio of binder to active material. When the active material has a higher density than the binder material, the active material may be deposited toward the outside of the centrifuge, leaving a layer of excess binder material that may perform as a separator layer.

In some embodiments, an electrode may be constructed with conventional processing techniques and a separator layer may be added to the electrode using a centrifugal processing step. In such an embodiment, the separator layer may have increased adhesion to the electrode. In some embodiments, such a separator layer may include a solid, paste, or gel electrolyte that may infiltrate the active material of the electrode during centrifugal processing.

FIG. 2 is a flowchart illustration of an embodiment 200 showing a method for fabricating an electrochemical device. Embodiment 200 illustrates a manufacturing method for a device such as a battery or capacitor that uses two separately manufactured electrodes that are laminated to a separator. Each electrode may be processed in a centrifuge and may undergo additional secondary processing.

Many different manufacturing methods and sequences may be used to construct a device using centrifugal processing.

An anode manufacturing process 228 and a cathode manufacturing process 230 may have similar sequences. After manufacturing the electrodes, the separator manufactured in block 218 is laminated in block 220 to the electrodes and an electrolyte 222 is added in block 224 to produce the device in block 226.

The anode and cathode manufacturing processes 228 and 230 may begin by adding binder to active material in blocks 202 and 204, respectively. The binder and active material mix may be a dry powder mix or a mix with a transport mechanism such as a liquid. In some cases, the liquid may be a solvent in which the active material or binder may be dissolved. Additional materials may also be introduced to the mix, including pore forming agents, electrolyte materials, conductive diluents such as carbon powders, or other materials.

In many embodiments, the mixture may be a paste, liquid suspension, slurry, gel, solution, or other form. The mixture may be manufactured with a transport media to enable pumping, pouring, spraying, dispersing, or other manufacturing processes to handle or manipulate the mixture.

In some embodiments, active material may be processed without a binder. In some such embodiments, active material may be applied directly to a current conductor, which may act to give the electrode some mechanical properties for processing and handling.

The active material and binder may be processed in a centrifuge in blocks 206 and 208 for the anode and cathode, respectively. The materials may be introduced into the centrifuge process in many different manners. In some cases, the material may be applied to a coupon or cylindrical surface of the centrifuge before beginning rotation. In other cases, the material may be introduced to the centrifuge while the centrifuge is rotating by spraying, pouring, or another method.

The processing characteristics of the centrifuge process may vary from one implementation to another. In some cases, especially when the specific gravity of a binder and active material are close, such as within 20 percent of each other, a high gravitational force may be used for an extended period of time. In other cases, where the specific gravity of the binder and active material may be different from each other, such as greater than 20 percent, lower gravitational forces and less time may be applied using the centrifuge.

Many embodiments may use a transport medium to move and manipulate the active material before and during processing. The transport medium may be any liquid, gas, or other particulate material that assists in processing. For example, a liquid such as water may be used to suspend active material and binder together. The suspended material may be deposited and consolidated in a centrifuge with the transport medium being partially or completely drawn off. In some cases, the transport medium may comprise two or more different materials, such as a solvent and a pore forming agent. In such a case, the solvent may be drawn off during the centrifugal processing and the pore forming agent may be extracted in a subsequent process step. In some embodiments, the centrifugal processing steps of blocks 206 and 208 may include extracting some or all of a transport medium. In such embodiments, transport medium may be collected from the surface of the centrifuged material. Other embodiments may apply vacuum and/or heat to the centrifuge to facilitate chemical reactions or evaporation to remove the transport mechanism, form pores, or other purposes.

In some embodiments, a dry powder of active materials may be compacted using a centrifuge and then a binder may be applied and allowed to infiltrate the compacted active material during centrifuging. Such a binder may be sprayed onto a compacted or partially compacted layer of active material in the centrifuge.

In many cases, the centrifuged material may result in a thin film of electrode material. In other cases, the resultant material may be a bulk form of compacted material, such as a paste or slug. The bulk material may be subsequently formed into an electrode. In the case of a thin film, the resultant film may undergo some additional processing or may be laminated directly to a separator.

In blocks 210 and 212, secondary processing may be applied to the anode and cathode electrodes, respectively. Secondary processing may include any type of pressing, calendaring, casting, extrusion, or other process. In many cases, the secondary processing may be used in porous binder materials for extracting pore forming materials through evaporation, leaching, pressing, or other mechanism.

In blocks 214 and 216, the processed electrode material may be attached to a current collector. In a typical process, electrode material may be joined to a current collector using mechanical force, such as pressure applied by a roller. In some processes, heat may also be applied. An adhesive or other material may be present to join the electrode to the current collector.

The current collector may be any type of conductive material. In some instances, a thin film of metal or metalized material may be used. In other instances, a metalized material may be applied to the electrode material. A current collector may also be a grid, mesh, screen, or other form of conductive material.

In some embodiments, a current collector may be formed or placed into the centrifuge and the active material and binder may be processed on top of the current collector. In such an embodiment, the current collector may give the assembled materials some physical strength and improve subsequent handling and processing of the assembled materials after centrifugal processing.

Some embodiments may apply the centrifuged electrode material to a current collector in a paste, gel, or other form. The electrode material may be cast, sprayed, extruded, or formed onto the current collector.

In the case of a cylindrical battery of the type known as a bobbin cell, electrode material may be centrifuged in the case or console of the battery by rotating the cylindrical console along the axis of the cylinder. Such a rotating action may act to compact active material against the outer sides of the console and leave excess transport material in the center of the console. The excess transport material may be removed from the center of the console. In some embodiments, additional active material may be added in place of the extracted transport material or an electric terminal pin may be inserted into the void space to form one of the contact pins for the cell. Such a technique may be applied to alkaline, nickel metal hydride, or other types of non rechargeable or rechargeable cylindrical batteries.

The separator may be manufactured in block 218 and laminated to the two electrodes in block 220. The separator may be manufactured in a separate manufacturing process. In many such cases, the separator may be formed in a film that is easily laminated. In some cases, the separator may be formed in situ by spraying or applying separator material in lieu of laminating.

In some embodiments, excess binder material may be used in the centrifugal process to form a layer of binder material on the surface of the active material. In such a case, the excess binder material may serve as an integral separator. Such an integral separator may be formed in one or both of the anode and cathode electrodes.

Electrolyte in block 222 may be added to the assembled device in block 224 to produce the device in block 226. The electrolyte may be a liquid, paste, gel, or other material. In some instances, an electrolyte may be a solid but ion conducting material.

In some embodiments, the electrolyte may be added during a centrifugal process so that the electrolyte may infiltrate the active material. In such an embodiment, active material may be consolidated with or without a binder and the electrolyte may then be added in the centrifuge and allowed to infiltrate the active material. When the electrolyte has a specific gravity that is much greater or much less than the active material and binder, a strong binder may be used to prevent a centrifugal electrolyte infiltration process from collapsing or upsetting the active material and binder structure. When the specific gravity of the electrolyte is close to specific gravity of the active material and binder structure, a binder that is less structural may be used.

Embodiment 200 is merely one method for constructing an electrochemical device using a centrifuge to consolidate active material. In some instances, multiple manufacturing steps may be performed in the centrifuge, including attaching various layers, joining two or more layers, forming layers in situ, adding and infiltrating electrolyte, applying a binder material, or other processes. Such manufacturing processes may be adaptable to forming thin films layers of materials that are directly formed into a electrochemical device or done so with a minimum of additional processing.

In some instances, active material may be consolidated or compacted using a centrifuge to form a slug, densified paste, or other form that is subsequently processed in a more conventional battery manufacturing method.

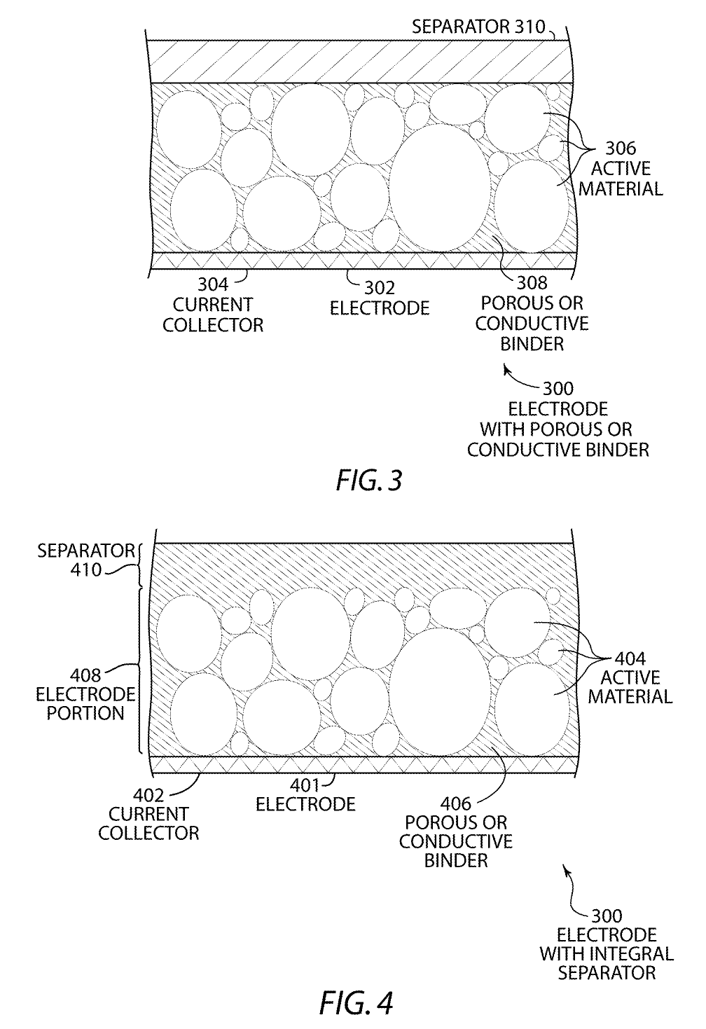

FIG. 3 is a schematic illustration of an embodiment 300 showing a cross section of an electrode with porous or conductive binder. The electrode 102 has a current conductor 304 with some active material 306 held in a matrix of porous or conductive binder 308. A separator 310 is applied to the electrode 302.

The embodiment 300 illustrates an active material 306 that may be densified or compacted using a centrifuge. The matrix of a binder 308 may hold the active material 306 in place for stability during manufacturing and durability in a finished device. The binder 308 may be a porous binder with pores sized smaller than the smallest nominal size of the active material 306. In some embodiments, the smallest active material particle size may be 10 times or more larger than the nominal pore size of the binder.

In some cases, a solid conductive binder 308 may be used. Such a binder may also serve as a solid electrolyte. When a solid conductive binder is used, it may be desirable to have very few voids between the conductive binder and the active material. Similarly, a porous binder may also be applied in a manner that few voids are present, other than the pores within the porous binder.

The separator 310 in embodiment 300 may be a separately applied film that is attached by heat, pressure, or another process or combination of processes. The separator 310 may be applied by spraying, extruding, casting, or other process whereby the separator 310 may be applied with a transport media. The transport media may be evaporated or otherwise removed to leave the separator 310.

In some embodiments, the separator 310 and/or the current collector 304 may be used to provide mechanical stability and durability to the assembly during manufacturing and use.

The active material 306 is illustrated in many different particle sizes, including particles that may be 10 times or more larger than the size of a smaller particle. In other embodiments, the pore size may be the same nominal size or even larger than the smallest size of active material particles. In some embodiments, a mixture of large and small particles may result in denser electrodes during the centrifugal process step than uniform sized particles.

In some embodiments, the pore size may be larger than the size of the smallest size of the active material particles. By using a centrifugal compaction process, the active materials may be mechanically interlocked so that small particles of active material may not migrate and cause shorts or other problems. Additionally, a porous binder may aid in holding the compacted and mechanically interlocked particles together.

In a typical version of embodiment 300, the composition may be between 40% and 70% by volume active material, with 2% to 30% by volume porous binder having 50-90% micropores. The remaining volume may be voids.

FIG. 4 is a schematic illustration of an embodiment 400 showing a cross section of an electrode with a porous or conductive binder. The electrode 401 has a current collector 402, active material 404, and a porous or conductive binder 406. The electrode 401 has an electrode portion 408 and a separator 410. The separator portion 410 may be made from the porous binder material 406.

Embodiment 400 is similar to embodiment 300 with the exception that excess porous or conductive binder 406 forms the separator 410. During a centrifugal process step, centrifugal forces may force the active material 404 to consolidate against the current collector 402 and excess porous or conductive binder 406 may rise to the surface to form the separator 410. Such a process is possible when the specific density of the active material is higher than the specific gravity of the porous or conductive binder 406.

When the porous or conductive binder 406 has a higher specific gravity than the active material 404, such a structure may be formed in a centrifuge, but the separator side would be toward the outer radius of the centrifuge.

The difference between the specific gravities of the active material 404 and the porous or conductive binder 406 may affect the centrifugal process step. When the difference is great, the active material 404 may separate with less time or force in the centrifuge. When the difference is small, the centrifugal processing time and/or force may be substantially higher to force the separation of the two materials.

In many embodiments, the active material 404 may be mixed with the binder material 406 in a liquid, paste, gel, slurry, or other form that uses a transport media. The transport media may function as a solvent for either or both of the active material 404 or porous or conductive material 406. In some embodiments, the transport media or a portion of the transport media may serve as a pore forming material for the binder.

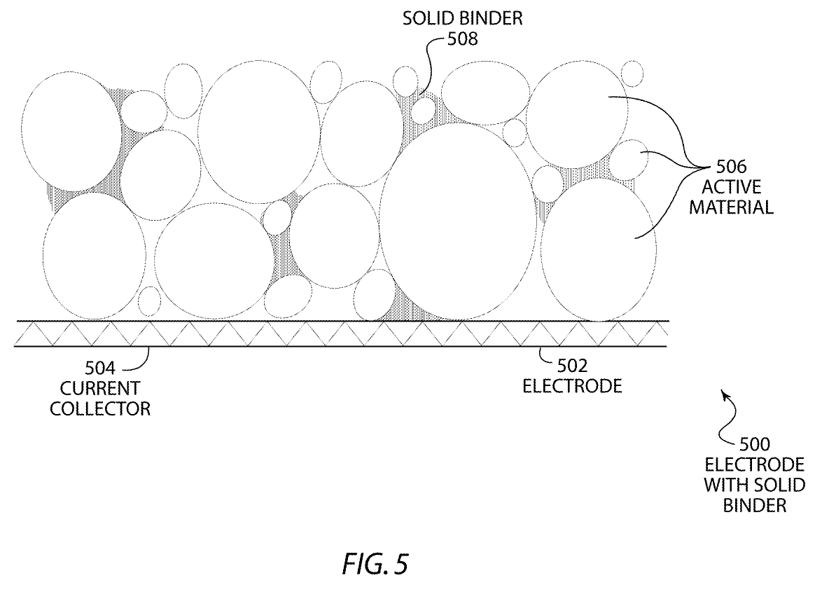

FIG. 5 is a schematic illustration of an embodiment 500 showing a cross section of an electrode with a solid binder. The electrode 502 has a current collector 504, active material 506, and a solid binder 508. The solid binder is dispersed around the active material 506 so that the active material 506 may be mechanically held but with some gaps to allow electrolyte to contact the active material 506.

Embodiment 500 may be formed using a centrifugal process step to consolidate the active material 506. In some embodiments, the solid binder 508 may be processed with the active material 506 in a centrifuge, while in other embodiments, the binder 508 may be applied after centrifugal processing.

A solid binder 508 may be applied using a transport media that contains the binder 508 in suspension or solution. During a centrifugal processing step, the solid binder 508 may be deposited or precipitated and bound with the active material 506.

In a typical version of embodiment 500, the composition may be between 40% and 70% by volume active material, with 5% to 30% by volume solid binder. The remaining volume may be voids.

The foregoing description of the subject matter has been presented for purposes of illustration and description. It is not intended to be exhaustive or to limit the subject matter to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments except insofar as limited by the prior art.

What is claimed is:

1. A method comprising:
adding a binder to a first active material to form an unprocessed electrode material;
mixing said first said first active material with said binder using a transport medium, said active material having a specific gravity that is at least 10 percent higher than a specific gravity of said transport medium;
processing said unprocessed electrode material in a centrifuge to produce a processed electrode material; and
constructing said first processed electrode material into an electrochemical device.

2. The method of claim 1, said transport medium being a gas or a liquid.

3. The method of claim 2, said gas being air.

4. The method of claim 1, said transport medium comprising a pore formation material adapted to form pores in said binder.

5. The method of claim 1, said binder being dissolved in said transport medium.

6. The method of claim 1, said unprocessed electrode material being in a slurry form or a powder form.

7. The method of claim 1, said binder being an ionic conductor.

8. The method of claim 1, said binder being a solid material that is non-conductive.

9. The method of claim 8, said battery being a lithium ion battery.

10. The method of claim 1, said constructing comprising:
attaching a current collector to said first processed electrode material;
connecting a separator to said first processed electrode material;
connecting a second electrode material to said separator; and
attaching a second current collector to said second electrode material.

11. The method of claim 10, said separator being connected to said first processed electrode material using a centrifuge.

12. A method comprising:
processing a first active material in a centrifuge, said first active material being a powder form;
adding a binder to said first active material; and
constructing an electrochemical device from said first active material and said binder.

13. The method of claim 12, said binder being added to said first active material either before, during, or after said processing.

14. The method of claim 12, said binder being a porous binder.

15. The method of claim 12, said binder being dissolved in a solvent.

16. The method of claim 12, said constructing comprising performing a secondary process to said first active material and said binder.

17. The method of claim 16, said secondary process comprising at least one of a group composed of:
calendaring;
pressing;
casting;
extruding; and
pouring.

18. An electrode comprising:
a first active material; and
a porous binder, said active material and said porous binder having been processed in a centrifuge and comprising an electrode portion comprising said first active material and said porous binder and a separator portion comprising said porous binder, said porous binder having a specific gravity less than a specific gravity of said first active material.

19. The electrode of claim 18, said separator portion and said electrode portion being formed in a single centrifuge process.

20. The electrode of claim 18, said separator portion and said electrode portion being formed by:
forming said electrode portion in said centrifuge;
adding a portion of said binder; and
forming said separator portion in a second centrifuge process.
